(19) United States
(12) Patent Application Publication
(10) Pub. No.: US 2015/0227650 A1
(43) Pub. Date: Aug. 13, 2015

(54) METHOD FOR MODELING ETCHING YIELD AND ETCHING SURFACE EVOLUTION SIMULATION METHOD

(71) Applicant: Tsinghua University, Beijing (CN)

(72) Inventors: Yixu Song, Beijing (CN); Cong Ruan, Beijing (CN); Yangfu Gao, Beijing (CN); Xiaomin Sun, Beijing (CN)

(21) Appl. No.: 14/431,508

(22) PCT Filed: Jul. 18, 2014
(86) PCT No.: PCT/CN14/82517

§ 371 Date: Mar. 26, 2015

(30) Foreign Application Priority Data
Jul. 19, 2013 (CN) 201310306649.1

(51) Int. Cl. G06F 17/50; G06F 17/10; H01J 37/32

(52) U.S. Cl. CPC G06F 17/5009; H01J 37/32926; G06F 17/10

(57) ABSTRACT

The present disclosure relates to a method for modeling an etching yield in the evolution simulation of a plasma etched surface, and belongs to the technical field of process simulation of etching surfaces in a micro-electronic processing technology. The method includes the following steps: performing parameterization representation on an etching yield model of various ions; obtaining optimal parameters in the etching yield model by adopting an optimization algorithm; in an optimization process, selecting some specific positions on the surface of a groove, and by comparing simulated etching rates at different time points in an evolution process with an actual etching rate, calculating the goodness (fitness value) of each group of model parameters as a basis of selecting the optimization algorithm and generating a next model parameter set; substituting the obtained model parameters into a model parameterization formula so as to obtain the etching yield model. By adopting the method, the parameters of the etching yield model of various ions can be optimized according to etching data, and the problem of inaccuracy in obtaining the etching yield parameters through an ion bombardment experiment method and a molecular dynamics method is solved.

### CROSS REFERENCE TO RELATED APPLICATIONS

This application claims priority to International Application No. PCT/CN2014/082517, filed on Jul. 18, 2014, which claims priority to Chinese Patent Application No. 2013103066491, filed with the Chinese Patent Office on Jul. 19, 2013 and entitled “Modeling method for etching yield and etching surface evolution simulation method,” all of which are incorporated by reference herein in their entireties.

### FIELD OF THE DISCLOSURE

The present disclosure relates to the technical field of etching process simulation in a micro-electronic processing technology, in particular to a method for modeling an etching yield and an etching surface evolution simulation method.

### BACKGROUND

In a plasma etching process, the properties of plasma itself and the action mechanism on a surface determine the etching quality. To deeply understand the mechanism of the etching process, an etching profile evolution method was proposed and combined with etching control process parameters and mechanisms to seek the reasons of special process results.

At present, the most common etching profile evolution method is a cell-based etching profile evolution method. The cell-based etching profile evolution method comprises the steps of dividing a simulated area into a plurality of cells containing different materials, then generating incident ions from the upper surface of each material by using a Monte Carlo method according to boundary ion distribution and incident angle distribution, and tracking the motion of the ions till they reach the surface of the material or leave the simulated area. If the ions reaching the surface of the material satisfy an etching condition, the number of etching atoms is calculated according to an etching yield model, and the atoms are subtracted from the cells where the atoms are located, so as to realize etching; otherwise, the ions are continuously tracked for the second time. When the number of the atoms in a cell is zero, the cell is converted into an empty cell, so that forward propulsion of the etching surface is realized. Thus it could be seen that, the cell-based etching profile evolution method depends on the etching yield model.

According to the results of existing documents, the etching yield of ions is also closely related to the incident energy and incident angle of the ions. At a certain incident angle, the etching yield of the ions is linearly related to the square root of the incident energy of the ions; and under certain energy, the etching yield and incident angle of the ions also satisfy a certain relationship. An example of parametric representation of a specific etching yield model of the ions is as shown in formula (1):

E_{Y}(E₊,θ)=C(\sqrt{E₊}\sqrt{Eₜₕ})ƒ−(θ) (1)

in formula (1), the function ƒ(θ) is expressed as:

$$f ( θ ) = \{ \begin{matrix}1 & θ \leq {θ}_{cr} \\ \frac{cos θ}{cos {θ}_{cr}} & θ > {θ}_{cr}\end{matrix} \qquad ( 2 )$$

wherein C, Eₜₕ and θ_{cr} are parameters to-be-optimized for establishing the model.

It could be known from formulas (1) and (2) that, the etching yield model is determined by the model parameters (θ_{cr}, Eₜₕ, C) of the etching yield, so the model parameters (θ_{cr}, Eₜₕ, C) of the etching yield are very important for the cell-based etching profile evolution method.

There are mainly two conventional methods for constructing an etching yield model: an ion bombardment experiment method and a molecular dynamics method. The ion bombardment experiment method mainly comprises the steps of bombarding the surface through ions generated by an instrument and having specific rate and angle and then analyzing the etching result to obtain an average ion etching rate; and the molecular dynamics method, which simulates the action of the ions on the etched surface by using classical mechanics, actually is a theoretical calculation method, and the precision of the molecular dynamics method depending on the accuracy of a potential function. The physicochemical reaction in the actual process is extremely complex, and the etching yield always needs to reflect the interaction between various ions, thus actually both of the two methods cannot simulate the actual processing environment, so the obtained etching yield is always a qualitative trend result. When the cell-based etching profile evolution method is used for the simulation, great error is often produced with respect to the actual processing result. In an ion etching yield modeling method proposed recently, the etching yield model of the ions is solved by combining an optimization method and an etching profile evolution method. However, this method cannot simultaneously optimize several etching yield model corresponding to different various ions, and the calculation time is relatively long since the etching profile evolution method is utilized.

A multiobjective evolutionary algorithm based on decomposition (MOEA/D) proposed a few years ago is widely applied in solving a multiobjective problem. According to the algorithm, weight vectors distributed uniformly are selected, and then the multiobjective optimization problem is converted into a single-objective optimization problem by using a decomposition-based method, so that the problems of fitness value grading, diversity maintenance and the like in the MOEA based on a distribution relationship are avoided. Meanwhile, on the selection of evolutionary operators, a differential evolutionary operator serving as a crossover operator in the MOEA/D algorithm evolution process can also obtain more excellent filial generation.

### SUMMARY

One object of the present disclosure is to provide a method for modeling an etching yield in the evolution simulation of a plasma etched surface for overcoming the defects of the prior art.

According to an aspect of the present disclosure, there is provided a method for modeling an etching yield in the evolution simulation of a plasma etched surface, including the steps of performing parametric representation on an etching yield model, calculating a group of optimized model parameters by adopting an optimization algorithm and using the mean square errors between simulated etching rates of selected positions of a groove at different moments during the evolution process and an actual etching rate as optimization objectives, and substituting the obtained model parameters into a formula so as to obtain the etching yield model.

In one embodiment, the method includes the following steps:

1) setting the value ranges for etching yield model parameters, designing etching processes with different time-lengths and with different parameters, and obtaining p groups of actual etching rates Vᵣ at different etching time points and at different profile positions of etching profiles with different widths by analyzing a profile picture with a scanning electron microscope, or by simulating an intermediate process for a given processing profile by using an etching profile evolution algorithm;

2) selecting an optimization algorithm for optimizing the etching yield model parameters and setting initial parameters of the optimization algorithm, maximum execution times Nₘₐₓ and precision eps of the optimization algorithm and initial parameters of incident ions at preselected positions on the surface of a groove;

3) generating an initial model parameter set consisting of Nₚₒₚ groups of model parameters as well as an elite population and initial vectors of the optimization algorithm according to the requirements of the optimization algorithm and the value ranges of the etching yield model parameters;

4) calculating the fitness value of each group of model parameters in the etching yield model parameter set by using the relationship between the etching yield and the etching rate;

5) searching, by using the optimization algorithm, for and determine a next model parameter set according to the fitness value of each group of model parameters;

6) repeating steps 4)-5) till the maximum execution times Nₘₐₓ is reached or till the optimal value of the current generation satisfies the specified precision eps compared with the optimal value of the last generation, and taking the current model parameter set as an optimized model parameter set; and

7) selecting optimal model parameters from the optimized model parameter set, outputting the optimal model parameters, and substituting the optimal model parameters into an etching yield model parameterization representation formula so as to obtain an etching yield model.

2. The method of claim 1, characterized in that step 4) specifically includes:

4.1) with each group of parameters in the model parameter set and the initial parameters of the incident ions at specific positions on the surface of the etching groove as input, calculating the etching rates Vₛ of the incident ions at these specific positions by using the relationship between the etching yield and the etching rates;

4.2) for p groups of grooves with different widths respectively, for the k^{th} group of grooves, calculating the error of the simulated etching rate Vₛ relative to the actual etching rate Vᵣ according to formula (3) as follows:

$${E}_{k} = {\sum }_{i = 1}^{n} {\sum }_{j = 1}^{m} w ( i , j ) {( {V}_{rij} - {V}_{sij} )}^{2} \qquad ( 3 )$$

wherein in the formula, n indicates the number of different profiles in the evolution process of the k^{th} group of grooves, m indicates the number of preselected positions on each profile in the evolution process of the k^{th} group of grooves, Vᵣᵢⱼ the actual etching rate of the j^{th} position on the i^{th} profile of the k^{th} group of grooves, Vₛᵢⱼ indicates the simulated etching rate of the j^{th} position on the i^{th} profile of the k^{th} group of grooves, w(i,j) indicates the influence degree of the mean square error between the simulated etching rate of the j^{th} position of the i^{th} profile of the k^{th} group of grooves and the actual etching rate on the global error;

4.3) obtaining the fitness value F=(1/E₁, 1/E₂, . . . , 1/Eₚ) of this group of model parameters by using 4.2); and

4.4) repeating 4.1)-4.3), and calculating the fitness value of each group of parameters in the model parameter set.

According to another aspect of the present disclosure, a method for modeling an etching yield model in the evolution simulation of a plasma etched surface is provided, including: (1) obtaining a set of actual etching rate samples; (2) selecting a form of the etching yield model, and determining parameters to be determined in the etching yield model; and (3) optimizing the parameters to be determined in the etching yield model by using a predefined optimization algorithm, wherein the optimization objective of the optimization algorithm involves minimizing the difference between an actual etching rate and a corresponding simulated etching rate, and the corresponding simulated etching rate is obtained by using the predefined relationship between the etching yield model and the etching rate.

According to a further aspect of the present disclosure, a plasma etched surface evolution simulation method is provided, including the steps: 1) initializing an etching profile evolution model, and setting an initial inclination angle φ of a mask side wall; 2) performing simulation by using a cellular automaton method, and operating a predefined number of time steps; 3) adjusting the inclination angle φ of the mask side wall according to a predefined formula; and 4) judging whether the evolution reaches a termination condition, if so, terminating the evolution, otherwise, returning to step 2).

The embodiments of the present disclosure have the following characteristics and beneficial effects:

according to the method of the embodiments of the present disclosure, parametric representation is performed on an etching yield model of various ions; optimized parameters in the etching yield model are obtained by adopting an optimization algorithm; in an optimization process, some specific positions on the surface of the groove are selected, and by comparing simulated etching rates with actual etching rates at different time points in an evolution process, the goodness (fitness value) of each group of model parameters is calculated as a basis of selecting the optimization algorithm and generating a next model parameter set; and the obtained model parameters are substituted into a model parameterization formula so as to obtain the etching yield model.

According to the present disclosure, the parameters of the etching yield model of various ions can be optimized according to etching data, and the problem of inaccuracy in acquisition of the etching yield parameters through an ion bombardment experiment method and a molecular dynamics method is solved.

### DETAILED DESCRIPTION

The present disclosure provides a method for modeling an etching yield in the evolution simulation of a plasma etched surface, which will be described in detail below in combination with embodiments.

The “actual etching rate” herein indicates an etching rate calculated on the basis of etching profiles obtained by actual processing at different moments in an actual plasma etching process.

For example, the actual etching rate may be the one obtained by dividing the distance by time on the basis of the depth of each point at different moments. However, under the condition that sampling points are not dense enough, the etching profile at a certain intermediate moment is not actually observed. At the moment, the actual etching rate of each point of the etching profile may be obtained, for example, by simulating the intermediate process via an etching profile evolution algorithm.

An example of a method for modeling an etching yield model used in the evolution simulation of a plasma etched surface according to an embodiment of the present disclosure will be described below.

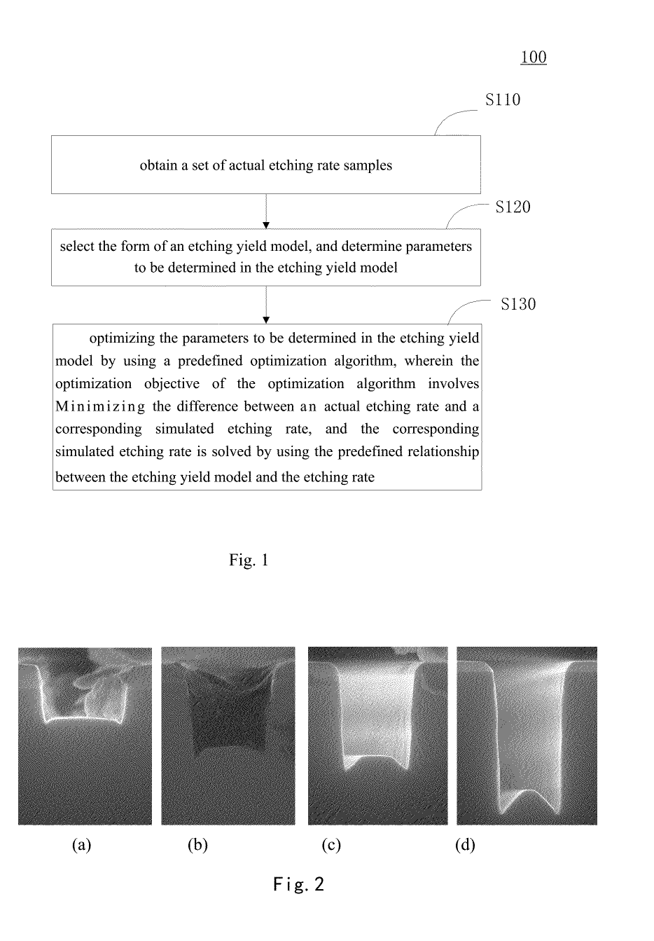

FIG. 1 shows an overall flow diagram of a method 100 for modeling an etching yield model used in the evolution simulation of a plasma etched surface according to an embodiment of the present disclosure.

In step S110, a set of actual etching rate samples is obtained.

In an example, the obtained actual etching rate samples are p groups of actual etching rates Vᵣ at different etching time points and at different profile positions of etching profiles with different widths, and the etching profile of each width corresponds to a group of actual etching rates Vᵣ at different etching time points and at different profile positions, wherein p is an integer more than or equal to 1, and the number of actual etching rates Vᵣ at different etching time points and at different profile positions in each group is more than or equal to 1. The evolution results of the etching profiles with multiple widths are selected in this embodiment on the basis of the following consideration: in an actual etching process, if the etching evolution profile with only one width is selected, a great error between the measured actual etching rate and the real value is easily produced due to the error of an experiment itself, and then the difference between the simulated etching rate and the actual etching rate also produces a great error. Therefore, the evolution results of the etching profiles with multiple widths are selected in this preferred embodiment, to reduce the error.

To solve the etching rates at etching surface points, the etching profiles at different moments in the etching process may need to be obtained. However, in the actual plasma etching process, for a same etching silicon chip, etching profile pictures at different moments cannot be obtained at intervals in a manner of scanning with a scanning electron microscope. The reason is that before the scanning electron microscope is used every time for scanning, the silicon chip needs to be processed, so that the next etching environment is different from the last one.

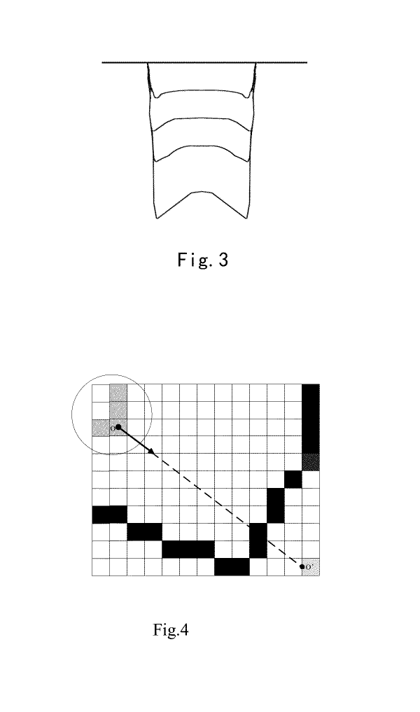

To solve the problem, in an example, the step of obtaining the set of actual etching rate samples includes: selecting a plurality of silicon chips made of the same material and having the same size, performing the same pretreatment on the silicon chips before etching, then etching for different time on the silicon chips which are numbered differently in a same etching environment, regarding the etching profile results of these silicon chips as the etching results of a same silicon chip at different moments, and analyzing the etching results of the same silicon chip at different moments to obtain the actual etching rate at each point on each etching profile. FIGS. 2(a), (b), (c) and (d) respectively show the etching results (the external visual appearances of etching depths or etching distances) after four silicon chips are etched for different time, specifically after the four silicon chips are etched for 1, 2, 3 and 4.5 minutes, and these etching results are used as the ones of a same silicon chip after being etched for 1, 2, 3 and 4.5 minutes. In this embodiment, a plurality of silicon chips made of a same material and having a same size are selected and pretreated in the same manner before etching, and then the silicon chips with different numbers (that is, numbered differently) are etched for different time in the same etching environment. The etching environment is consistent, so the etching morphology of a silicon chip at different moments may be approximately reproduced by the method, and the etching profile results of these silicon chips may be regarded as the etching results of a same silicon chip at different moments.

In another example, the step of obtaining the actual etching rate further includes: for a given processing profile without actual etching data, simulating an intermediate process by using an etching profile evolution algorithm to obtain the actual etching rate of each point of the given processing profile. For example, if only the etching results at the 1^{st}, 2^{nd}, 3^{rd} and 4.5^{th} minute exist, the etching results at the 1.5^{th}, 2.5^{th}, 3.5^{th} minute may be obtained by interpolating.

For the etching profiles with the same etching width at different moments, corresponding etching lines are extracted on the same picture via an image processing method and expressed as a cellular model, as shown in FIG. 2, which shows etching lines extracted from corresponding etching profiles. In the cellular model, the attribute of each cell occupied by the etching lines is set as “1” (black box in FIG. 2); and the attribute of each cell not occupied by the etching lines is set as “0” (white box in FIG. 2). An exemplary method for solving the etching rates of selected points on the etching lines by using the model will be described below.

For the cellular etching model as shown in FIG. 4, to solve the etching rate of a selected point O on the etching surface, two pieces of information need to be known: the normal vector of the point O and the crossing point O′ of the normal vector direction of the point O and the etching line of next moment. The normal vector may be solved according to an expression obtained by fitting occupied cells within a certain distance range of the point O. For the crossing point O′, because the distribution of points on the etching line does not have a specific law, the position of the crossing point O′ can be directly solved. According to a conventional solution, the point O advances with a certain step length along the normal vector till crossing with the etching line of the next moment, and the crossing point is the point O′. When the cellular model is relatively large, the efficiency of the method is relatively low.

A bisection method for quickly solving the position of the point O′ will be introduced below.

First, a point Y below the etching line is sought at a position located long enough along the direction of the normal vector, and a point X is set as the point O. Then, the midpoint Z of X and Y is selected, and whether the point Z is positioned on the etching line is judged. If the point Z is positioned on the etching line, the point Z is the solved point O′; and if the point Z is positioned below the etching line, Y is set as the point Z, otherwise, X is set as the point Z. The condition judgment process is repeated till the point O′ is found.

Because the etching rate itself is very small, the etching rate of the point O may be approximately solved by adopting formula (1) below:

$${v}_{o} = \frac{{OO}^{′}}{Δ t} \qquad ( 1 )$$

wherein OO′ indicates the distance from the point O to the point O′, and Δt is a time interval between the two etching lines.

In addition, on the aspect of selecting a selected point on the etching surface to solve the etching rate of the point, if points are uniformly selected as selected points on the etching line, it is difficult to reflect the distribution of the etching rates on the whole etching line, and especially at two ends of the bottom of a groove, the etching rates solved via differently distributed selected points have great difference. Accordingly, for accurately representing the etching rate condition, positions with relatively large etching rate changes on the etching line are mainly selected. In an example, for the set of actual etching rate samples, the sampling density at the bottom of the groove is greater than that on the lateral surface of the groove.

Return to FIG. 1, after the set of actual etching rate samples is obtained in step S110, it moves to step S120.

In step S120, the form of an etching yield model is selected, and parameters to be determined in the etching yield model are determined.

In an example, the form of the selected etching yield model is as shown in formula (2):

E_{Y}(E₊,θ)=C(\sqrt{E₊}\sqrt{Eₜₕ})ƒ−(θ) (2)

wherein C and Eₜₕ indicate parameters related to an etching process; θ indicates the angle of incident ions; ƒ(θ) indicates a function related to the incident angle in the etching process; E₊ indicates the energy of the incident ions;

in formula (2), the function ƒ(θ) is as shown in formula (3):

$$f ( θ ) = \{ \begin{matrix}1 & θ \leq {θ}_{cr} \\ \frac{cos θ}{cos {θ}_{cr}} & θ > {θ}_{cr}\end{matrix} \qquad ( 3 )$$

wherein C, Eₜₕ and θ_{cr} are parameters to be optimized for establishing the etching yield model.

In another example, an error term may also be considered in the form of the etching yield model, as shown in formula (4) below:

E_{Y}(E₊,θ)=C(√ \sqrt{Eₜₕ})ƒ( )e(E₊,θ) (4)

Wherein the e(E₊, θ) error term may adopt a polynomial fitting form using a trigonometric function (cos θ, sin θ and the like) of energy and an angle as an independent variable or other form.

Return to FIG. 1, after step S120, it moves to step S130.

In step S130, the parameters to be determined in the etching yield model are optimized by using a predefined optimization algorithm, wherein the optimization objective of the optimization algorithm involves minimization of the difference between an actual etching rate and a corresponding simulated etching rate, wherein the corresponding simulated etching rate is solved by using the predefined relationship between the etching yield model and the etching rate.

In an example, a multiobjective evolutionary algorithm is used as the optimization algorithm, and each of multiple objectives involves each of p groups of differences between the actual etching rates and the simulated etching rates.

For example, for the profile evolution result of the k^{th} width, formula (5) may be defined as an error function:

$${e}_{k} ( x ) = {\sum }_{i = 1}^{n} {\sum }_{j = 1}^{m} w ( i , j ) {( {v}_{rij} ( x ) - {v}_{sij} ( x ) )}^{2} \qquad ( 5 )$$

wherein, x indicates an etching yield model parameter; n indicates the number of profiles used for optimization in the etching profile evolution process with the k^{th} width; m indicates the number of points selected for optimization on each etching evolution surface; vᵣᵢⱼ indicates the actual etching rate of the j^{th} selected position at the i^{th} profile under the k^{th} width, vₛᵢⱼ indicates the simulated etching rate corresponding to the actual etching rate vᵣᵢⱼ; and w(i,j) is a weight factor, and indicates the influence degree of the deviation of vₛᵢⱼ relative to vᵣᵢⱼ.

Formula (6) below may be defined as an objective function for optimization, for example:

ƒ(x)=(e₁(x),e₂(x), . . . ,eₚ(x)) (6)

wherein p indicates the number of grooves with different widths in the etching evolution profiles.

Under such a condition, the optimized objective is to minimize the function ƒ(x), and to solve the corresponding x, so that the simulated etching rate is close to the actual etching rate as far as possible. Since ƒ(x) is a function vector, it cannot only optimize one component of the ƒ(x), and different components in the ƒ(x) need to be balanced. Accordingly, the parameter optimization problem of the etching yield model may be converted into a multiobjective optimization problem.

In another example, to study the error condition of all the etching profiles and focus on the influence of the error of a single etching profile on the global, the accumulated error sum Σeᵢ(x) of the etching profiles with different widths and the maximum error max(eᵢ(x)) of etching profiles with a single width may be used as optimization objectives to fulfill the purpose of comprehensively evaluating different eᵢ(x). On this basis, formula (7) may be defined as a new optimization objective function, so that the number of objectives is reduced to 2.

ƒ(x)=(Σeᵢ(x),max(eᵢ(x))) (7)

In an example, the parameters to be determined in the etching yield model are optimized by using a multiobjective evolutionary algorithm based on decomposition (MOEA/D). With respect to the introduction of the MOEA/D, reference may be made to an article entitled “MOEA/D: A Multiobjective Evolutionary Algorithm Based on Decomposition”, Zhang Q, Li H, et al., published on IEEE T. Evolut. Comput. 11 712 in 2007.

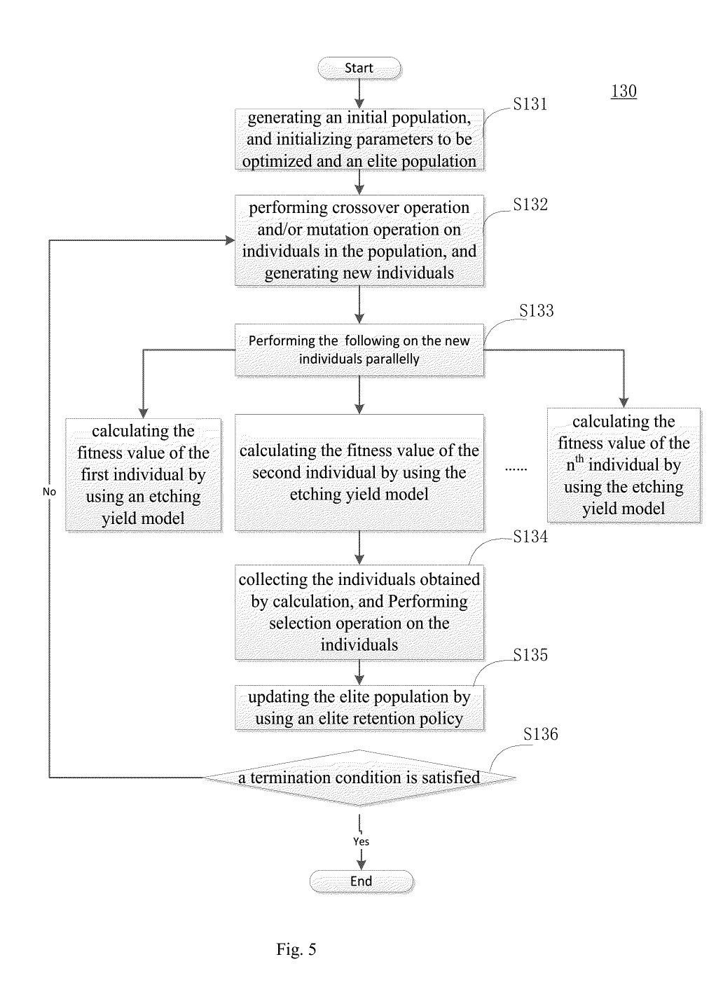

FIG. 5 shows a flow diagram of a method 130 for optimizing parameters to be determined in the etching yield model based on the MOEA/D according to an embodiment of the present disclosure.

As shown in FIG. 5, in step S131, an initial population is generated, and parameters to be optimized and an elite population are initialized.

In step S132, crossover operation and/or mutation operation are/is performed on individuals in the population to generate new individuals.

In step S133, corresponding simulated etching rates are calculated in parallel for the individuals by using the relationship between the etching yield model and the etching rates, and the fitness value of each individual is calculated on the basis of the difference between the actual etching rate and the simulated etching rate. For example, the fitness value of a first individual is calculated by a first processing unit with the etching yield model, the fitness value of a second individual is calculated by a second processing unit with the etching yield model, and the like.

In step S134, the calculated individuals are collected, and selection operation are performed on the individuals.

In step S135, the elite population is updated by using an elite retention policy.

In step S136, it is determined whether a termination condition is reached, if so, the processing is terminated; otherwise, the processing returns to step S132. In an example, to reduce data transmission in the parallel process, before a parallel algorithm is executed, experimental data related to etching are transmitted to corresponding nodes first, so that only corresponding parameter data need to be transmitted when the fitness value is calculated every time.

In an example, for a specific position, the step of solving the simulated etching rate at a specific position by using the predefined relationship between the etching yield model and the etching rate may include: solving the etching rate Vₛ_{ᵢ} of the i^{th} kind of ions by using the following predefined relationship between the etching yield E_{Y}_{ᵢ} and the etching rate Vₛ_{ᵢ} of the i^{th} kind of ions at the specific position, wherein the predefined relationship may be as shown in formula (8) below:

E_{Y}_{ᵢ}=Vₛ_{ᵢ}Nₜ×/J₊ (8)

wherein E_{Y}_{ᵢ} represents the etching yield of the i^{th} kind of incident ions at the specific position; Vₛ_{ᵢ} represents the etching rate of the i^{th} kind of incident ions at the specific position; Nₜ represents the material density of the i^{th} kind of incident ions; and J₊ represents the flowrate of the i^{th} kind of incident ions.

Then the simulated etching rate at the specific position may be as shown in formula (9):

$${V}_{s} = {\sum }_{i = 1}^{{N}_{ion}} {V}_{{s}_{i}} \qquad ( 9 )$$

wherein Nᵢₒₙ is the number of kinds of the incident ions.

The above-mentioned method for calculating the simulated etching rate is only exemplary, and other methods for calculating the simulated etching rate may be adopted.

A more specific example of the method for modeling the etching yield model according to an embodiment of the present invention will be described below.

The method for modeling the etching yield model according to an embodiment of the present disclosure may include the following steps:

1) setting the value ranges of etching yield model parameters, and obtaining p groups of actual etching rates Vᵣ at different etching time points and at different profile positions of etching profiles with different widths, either by designing etching processes with different time and different parameters, and analyzing a profile picture by using a scanning electron microscope, or by simulating an intermediate process for a given processing profile by using an etching profile evolution algorithm, wherein p indicates the number of grooves with different widths in the etching evolution profile (p is a positive integer and is within 2-5, and the value of p in an example is 2), the form of the etching yield model adopted in an example is as shown in the following formula:

E_{Y}(E₊,θ)=C(\sqrt{E₊}\sqrt{Eₜₕ})ƒ−(θ)

wherein the function ƒ(θ) is expressed as:

$$f ( θ ) = \{ \begin{matrix}1 & θ \leq {θ}_{cr} \\ \frac{cos θ}{cos {θ}_{cr}} & θ > {θ}_{cr}\end{matrix}$$

wherein C, Eₜₕ and θ_{cr} are parameters to be optimized for establishing the model; the definition and value range of each parameter may be respectively: Cε[0.01,30] and Eₜₕ ε[0,50] which are constants related to the etching environment; θ_{cr} ε[20°,50°] is a corresponding angle when the shape of an ion etching yield curve is changed along with the incident angle 0°→90° and the etching yield is changed for the first time; E₊ and θ are the attributes of ions themselves; E₊ is the energy of the incident ions; and θ is the incident angle of the incident ions;

2) selecting an optimization algorithm for optimizing the etching yield model parameters and setting initial parameters of the optimization algorithm, maximum execution times Nₘₐₓ and precision eps of the optimization algorithm and initial parameters of incident ions at preselected positions on the surface of a groove, specifically including:

2.1) setting the initial parameters of the optimization algorithm: for example, selecting a multiobjective evolutionary algorithm based on decomposition (MOEA/D) as an optimization algorithm, and selecting a differential evolutionary operator as the crossover evolutionary operator; expressing a model parameter set as a population, each group of model parameters being an individual of the population; setting the following initial parameters: population size Nₚₒₚ (the value of the population may be 100-500, and is 300 in this embodiment), individual neighbor number T (the value of the individual neighbor number is 30-50, and is 50 in this embodiment) for the evolution process of the MOEA/D, probability δ (the value of the probability δ is 0.5-0.8, and is 0.6 in this embodiment) of selecting individuals from neighbors of individuals as parents, crossover probability CR (the value of the crossover probability CR is 0.05-0.2, and is 0.1 in this embodiment) of the differential evolutionary operator, scale factor F (the value of the scale factor F is 0.5-1.0, and is 0.8 in this embodiment) of the differential evolutionary operator, and mutation probability pₘ (the value of the mutation probability pₘ is 0.05-0.2, and is 0.1 in this embodiment) of the differential evolutionary operator.

2.2) setting the maximum execution times Nₘₐₓ and precision eps of the optimization algorithm: setting the maximum execution times Nₘₐₓ (the value of the maximum execution times Nₘₐₓ is 50-150, and is 100 in this embodiment) and precision eps (the value of the precision eps of the MOEA/D is 0.000001-0.0001, and is 0.00001 in this embodiment) of the MOEA/D;

2.3) setting the initial parameters of the incident ions at multiple preselected positions on the surface of the groove: the initial parameters including the number of kinds Nᵢₒₙ of the incident ions at multiple positions, and the flowrate, angle distribution P_{θ} and energy distribution P_{E} of each kind of ions, which can be determined according to experimental data;

3) generating an initial model parameter set (initial population) consisting of Nₚₒₚ groups of model parameters (individuals), an elite population of the optimization algorithm and initial vectors consisting of initial weight vectors and a reference vector z, according to the value ranges of the initial parameters of the optimization algorithm and the etching yield model parameters in step 2);

3.1) randomly generating an initial population, the initial population totally having Nₚₒₚ individuals (wherein the i^{th} individual is expressed as xⁱ), each individual corresponding to a group of model parameters, each group of model parameters consisting of Nᵢₒₙ groups of parameters (θ_{cr}, Eₜₕ, C) (totally Nₚₐᵣₐ3 ᵢₒₙ parameters, Nₚₐᵣₐ indicating the number of parameters in each group of model parameters), and the value of each parameter in each group of model parameters being randomly generated within its value range;

3.2) generating Nₚₒₚ initial weight vectors distributed uniformly (the i^{th} vector being expressed as λⁱ and corresponding to the i^{th} individual, and the weight vectors being used for converting a multi-objective problem into a single-objective problem): supposing i^{th} vector λⁱ=(λ₁ⁱ, . . . , λₚⁱ), expressing i as ^{p}\sqrt{Nₚₒₚ} carry number system (i₁, . . . , iₚ)

$${( {i}_{1} , … , {i}_{p} )}_{\sqrt[p]{{N}_{pop}}} ,$$

and λⁱ can be expressed by formula (10):

$${λ}^{i} = ( \frac{{i}_{1}}{\sqrt[p]{{N}_{pop}}} , … , \frac{{i}_{p}}{\sqrt[p]{{N}_{pop}}} ) \qquad ( 10 )$$

3.3) initializing the elite population to be empty, the elite population being used for storing non-dominated solutions in the execution process of the optimization algorithm;

3.4) for i=1, . . . Nₚₒₚ, finding out T neighbor weight vectors closest to the weight vector λⁱ in Euclidean distance, and supposing that a set B(i)={i₁, . . . , i_{T}} is the serial number of T neighbor weight vectors corresponding to the weight vector λⁱ;

3.5) setting the initial reference vector z=(z₁, . . . , zₚ)^{T} of the optimization algorithm according to the prior knowledge of the problem, the components of z being used for storing the optimal fitness values of different etching evolution profile widths in the evolution process;

4) calculating the fitness value of each group of model parameters (individual) in the etching yield model parameter set (population) by using the relationship between the etching yield and the etching rate, specifically including:

4.1) with each group of model parameters (individual) in the etching yield model parameter set (population) and the initial parameters of the incident ions at the preselected positions on the surface of the groove as input, solving the etching yield E_{Y} by using an etching yield model formula, and then calculating the simulated etching rate Vₛ of each kind of ions at the position by using the formula (11) which represents the relationship between the etching yield and the etching rate:

E_{Y}_{ᵢ}=Vₛ_{ᵢ}Nₜ×/J₊ (11)

wherein E_{Y}_{ᵢ} represents the etching yield of the i^{th} kind of incident ions; Vₛ_{ᵢ} represents the etching rate of the i^{th} kind of incident ions; Nₜ represents the material density (number of atoms in a unit volume) of the i^{th} kind of incident ions; J₊ represents the flowrate of the i^{th} kind of incident ions;

then total simulated etching rate at the position is as shown in formula (12):

$${V}_{s} = {\sum }_{i = 1}^{{N}_{ion}} {V}_{{S}_{i}} \qquad ( 12 )$$

wherein Nᵢₒₙ is the number of kinds of the incident ions;

4.2) for p groups of grooves with different widths, for the k^{th} group of grooves, calculating the error of the simulated etching rate Vₛ relative to the actual etching rate Vᵣ according to formula (13):

$${E}_{k} = {\sum }_{i = 1}^{n} {\sum }_{j = 1}^{m} w ( i , j ) {( {V}_{rij} - {V}_{sij} )}^{2} \qquad ( 13 )$$

wherein in the formula, n indicates the number of different profiles in the evolution process of the k^{th} group of grooves, m indicates the number of preselected positions on each profile in the evolution process of the k^{th} group of grooves, Vᵣᵢⱼ indicates the actual etching rate of the j^{th} position on the i^{th} profile of the k^{th} group of grooves, Vₛᵢⱼ indicates the simulated etching rate of the j^{th} position on the i^{th} profile of the k^{th} group of grooves, and w(i,j) indicates the influence degree of the mean square error between the simulated etching rate of the j^{th} position of the i^{th} profile of the k^{th} group of grooves and the actual etching rate on the global error;

4.3) obtaining the fitness value F=(1/E₁,1/E₂, . . . , 1/Eₚ) of this group of model parameters by using 4.2);

4.4) calculating the fitness value of each group of model parameters in the model parameter set (population);

5) searching and forming the next model parameter set (population) by using the MOEA/D algorithm according to the fitness value of each group of model parameters (individuals), wherein differential evolutionary operators are selected as crossover evolutionary operators;

5.1) generating a random number R₁ in [0,1] as a reference value, if the random number R₁ is smaller than or equal to the probability δ of selecting individuals from neighbors as parents, then setting the set P as a set B(i), otherwise, setting the set as {1, 2, . . . , Nₚₒₚ};

5.2) implementing crossover operation by using differential evolutionary operators: supposing r₁=i, randomly selecting two numbers r₂ and r₃ from the set P, and generating new individuals y̅=( y̅₁, y̅₂, . . . , y̅_{N}_{ₚₐᵣₐ}) by using the differential evolutionary operators, wherein the calculation formula for each component y̅ₖ is as shown in formula (14):

$${\overline{y}}_{k} = \{ \begin{matrix}{x}_{k}^{{r}_{1}} + F ( {x}_{k}^{{r}_{2}} - {x}_{k}^{{r}_{3}} ) & {R}_{2} \leq CR \\ {x}_{k}^{{r}_{1}} & {R}_{2} > CR\end{matrix} \qquad ( 14 )$$

wherein R₂ is a random number in [0,1];

5.3) implementing mutation operation by using random mutation operators, to obtain mutated individuals y=(y₁, y₂, . . . y_{N}_{ₚₐᵣₐ}) through formula (15), for maintaining the diversity of the population and preventing obtaining local optimal solutions:

$${y}_{k} = \{ \begin{matrix}{\overline{y}}_{k} + {σ}_{k} ( {b}_{k} - {a}_{k} ) & {R}_{3} \leq {p}_{m} \\ {\overline{y}}_{k} & {R}_{3} > {p}_{m}\end{matrix} \qquad ( 15 )$$

wherein:

$${σ}_{k} = \{ \begin{matrix}{( 2 \times {R}_{4} )}^{0.05} - 1 & {R}_{4} \leq 0.5 \\ 1 - {( 2 - 2 \times {R}_{4} )}^{0.05} & {R}_{4} > 0.5\end{matrix} ,$$

aₖ and bₖ are respectively the lower bound and upper bound of the k^{th} parameter, R₃ and R₄ are random numbers in [0,1];

5.4) if the value of at least one component yᵢ(iε{1, 2, . . . , Nₚₐᵣₐ}) in the obtained individuals y=(y₁, y₂, . . . y_{N}_{ₚₐᵣₐ}) is not within the value range, then setting yᵢ as any random value in the value range;

5.5) updating the value of the reference vector z: for j=1, 2, . . . , p, if zⱼ<ƒⱼ(y), zⱼ=ƒⱼ(y);

5.6) updating the information of all neighbors x^{j} of the individual xⁱ in the population: for jεB(i), if the new individuals y=(y₁, y₂, . . . , y_{N}_{ₚₐᵣₐ}) and neighbors x^{j}=(x₁^{j}, x₂^{j}, . . . , x_{N}_{ₚₐᵣₐ}^{j}) satisfy formula (16):

$${max}_{1 \leq i \leq p} \{ {λ}_{i}^{j} \vert {f}_{i} ( y ) - {z}_{i} \vert \} < {max}_{1 \leq i \leq p} \{ {λ}_{i}^{j} \vert {f}_{i} ( {x}^{j} ) - {z}_{i} \vert \} \qquad ( 16 )$$

let x^{j}=y;

6) repeating steps 4)-5) by using the new population obtained in step 5) till reaching the maximum execution times Nₘₐₓ or till the optimal value of the current generation is smaller than the specified precision eps compared with the optimal value of the last generation, and taking the current model parameter set as an optimized model parameter set; and

7) selecting optimal model parameters (individuals) from the optimized model parameter set, outputting the optimal model parameters, and substituting the optimal model parameters into the etching yield model parameterization formula (1) and (2) so as to obtain the etching yield model in the plasma etching process.

According to an embodiment of the present disclosure, provided is a plasma etched surface evolution simulation method, including: (1) dividing a simulated area into a plurality of cells containing different materials; (2) generating incident ions from the upper surface of each material by using a Monte Carlo method according to boundary ion distribution and incident angle distribution; (3) tracking the motion of the ions in a simulative manner till reaching the surface of the material or leaving the simulated area; (4) judging whether the ions reaching the surface of the material satisfy an etching condition, if so, calculating the number of etching atoms according to an etching yield model, and subtracting the atoms from the cell where the atoms are located, so as to realize etching; and (5) otherwise, continuously tracking the ions for the second time.

The etching yield model is established through the following method: (1) obtaining a set of actual etching rate samples; (2) selecting a form of the etching yield model, and determining parameters to be determined in the etching yield model; and (3) optimizing the parameters to be determined in the etching yield model by using a predefined optimization algorithm, wherein the optimization objective of the optimization algorithm involves minimizing the difference between an actual etching rate and a corresponding simulated etching rate, and the corresponding simulated etching rate is solved by using the predefined relationship between the etching yield model and the etching rate.

In an example, the plasma etched surface evolution simulation method adopts a cell-based etching profile evolution method.

According to an embodiment of the present disclosure, a device for modeling an etching yield model used in the evolution simulation of a plasma etched surface is provided, including: an actual etching rate sample set obtaining component, configured to obtain a set of actual etching rate samples; an etching yield model and to-be-optimized parameter determining component, configured to select a form of the etching yield model and determine parameters to be determined in the etching yield model; and a parameter optimizing component, configured to optimize the parameters to be determined in the etching yield model by using a predefined optimization algorithm, wherein the optimization objective of the optimization algorithm involves minimizing the difference between an actual etching rate and a corresponding simulated etching rate, and the corresponding simulated etching rate is solved by using the predefined relationship between the etching yield model and the etching rate.

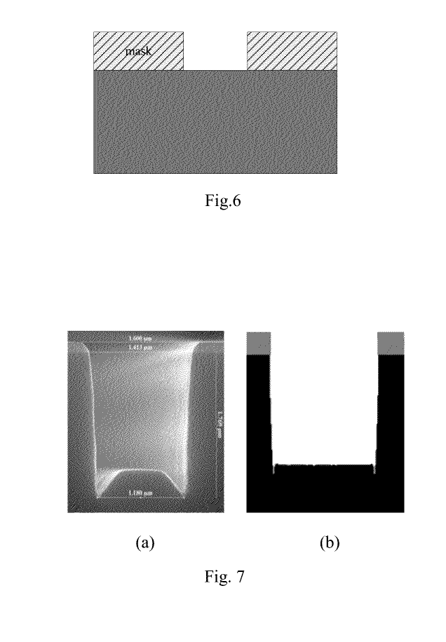

Conventionally, when an etching process is simulated by using a traditional cellular automation method, in order to reduce the calculation complexity, the side wall of an adopted mask is vertical, and the influence of the shape of the mask on the evolution of the etching surface is not considered. FIG. 6 shows an initial state of an etching surface evolution model adopted in the traditional cellular automaton simulation etching technology.

However, with the width increase of etching silicon chips, the difference between the etching experimental results and the simulation results is increasing. In FIG. 7, (a) and (b) comparatively show an etching experimental result and a simulation result. Moreover, under the condition that the side wall of the mask is kept vertical in the whole evolution process, when other etching process parameters related to the experimental conditions are modified, the simulation result is affected little. Accordingly, in the evolution process of simulating an etching profile with great width, if the side wall of the mask is kept vertical all the time, a groove shape in accordance with the experimental result cannot be simulated accurately.

Before the actual etching process, the side wall of the mask is processed first to keep a certain inclination angle. In this way, when the incident ions are shot into the side wall, the incident ions may be sufficiently shot into two sides of the bottom of a groove through reflection. Meanwhile, in the etching process, with the increase of the etching depth, the side wall of the mask is continuously bombarded by the ions, then a mask shrinkage phenomenon is produced, so that the inclination angle of the side wall of the mask is gradually reduced.

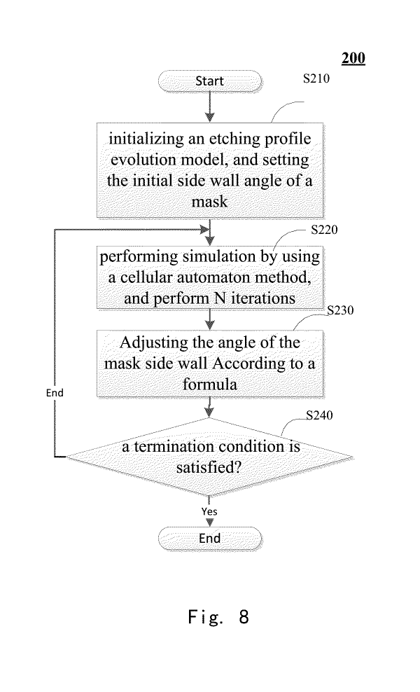

According to an embodiment of the present disclosure, there is provided a plasma etched surface evolution simulation method in consideration of the inclination angle of the side wall of the mask and the change thereof over time. FIG. 8 shows an overall flow diagram of the plasma etched surface evolution simulation method 200.

As shown in FIG. 8, in step S210, an etching profile evolution model is initialized, and an initial inclination angle φ of a mask side wall is set.

In step S220, simulation is performed by using a cellular automaton method, and a predefined number of time steps is operated.

In step S230, the inclination angle φ of the mask side wall is adjusted according to a predefined formula.

In step S240, whether the evolution reaches a termination condition is judged, if so, the evolution is terminated, otherwise, the operation returns to step S220.

In an example, the inclination angle φ of the mask is calculated according to formula (17) below:

$$φ = \{ \begin{matrix}{φ}_{0} - α t , & t < {φ}_{0} / α \\ 0 , & t \geq {φ}_{0} / α\end{matrix} \qquad ( 17 )$$

wherein φ₀ is the initial inclination angle of the mask side wall, t is the etching time, and α is a parameter for adjusting the inclination angle.

The above-mentioned plasma etched surface evolution simulation method considers the influence of the inclination angle of the mask side wall on the surface evolution process, and the inclination angle of the mask is adjusted over time, so that the actual etching process can be simulated more accurately.

It should be noted that, each component of the device for modeling the etching yield model and/or each step of the method for modeling the etching yield model may be realized by software programs, e.g. realized through combination of a CPU (central processing unit) in a general-purpose computer with an RAM (random access memory), an ROM (read-only memory) and software codes running in the CPU. The software programs may be stored in a storage medium such as a flash memory, a soft disk, a hard disk or an optical disk, and are loaded to the RAM during running and executed by the CPU. In addition, besides the general-purpose computer, they may also be realized through the cooperation between an application-specific integrated circuit and software. The integrated circuit is realized through at least one of an MPU (micro processing unit), a DSP (digital signal processor), an FPGA (field-programmable gate array), an ASIC (application-specific integrated circuit) and the like. In addition, each component of the device for modeling the etching yield model and each step of the method for modeling the etching yield model may be realized by special hardware, e.g. a specific FPGA, an ASIC and the like. In addition, each component of the device for modeling the etching yield model and each step of the method for modeling the etching yield model may also be realized via the combination of software and hardware.

According to an embodiment of the present disclosure, a non-instantaneous computer-readable medium is provided, on which an instruction set is stored. When being executed by a processor, the instruction set guides the processor to execute a method for modeling an etching yield model used in the evolution simulation of a plasma etched surface, wherein the method includes: (1) obtaining a set of actual etching rate samples; (2) selecting a form of the etching yield model, and determining parameters to be determined in the etching yield model; and (3) optimizing the parameters to be determined of the etching yield model by using a predefined optimization algorithm, wherein the optimization objective of the optimization algorithm involves minimizing the difference between an actual etching rate and a corresponding simulated etching rate, and the corresponding simulated etching rate is solved by using the predefined relationship between the etching yield model and the etching rate.

The structure and number of each component of the device for modeling the etching yield model and/or each step of the method for modeling the etching yield model do not limit the scope of the present invention. According to an embodiment of the present disclosure, the components and/or steps may be combined into an independent component and/or step to execute and realize corresponding functions and operations, or each component and/or each step are further split into smaller units to realize their respective functions and operations.

The embodiments of the present disclosure are described above, and the foregoing descriptions are exemplary rather than exhaustive and are not limited to the disclosed embodiments. Many modifications and alterations are obvious to those ordinary skilled in the art without departing from the scope and spirit of each described embodiment. Accordingly, the protection scope of the claims should prevail over the protection scope of the present disclosure.

1. A method for modeling an etching yield in evolution simulation of a plasma etched surface, the method comprising:
1) setting value ranges for etching yield model parameters, designing etching processes with different time-lengths and with different parameters, and obtaining p groups of actual etching rates Vᵣ at different etching time points and at different profile positions of etching profiles with different widths by analyzing a profile picture with a scanning electron microscope, or by simulating an intermediate process for a given processing profile through an etching profile evolution algorithm;
2) selecting an optimization algorithm for optimizing the etching yield model parameters and setting initial parameters of the optimization algorithm, and setting maximum execution times Nₘₐₓ and precision eps of the optimization algorithm and initial parameters of incident ions at preselected positions on surface of a groove;
3) generating an initial model parameter set consisting of Nₚₒₚ groups of model parameters as well as an elite population and initial vectors of the optimization algorithm according to requirements of the optimization algorithm and the value ranges of the etching yield model parameters;
4) calculating fitness value of each group of model parameters in the model parameter set by using relationship between an etching yield and an etching rate;
5) searching for and determining next model parameter set by using the optimization algorithm according to the fitness value of each group of model parameters;
6) repeating steps 4)-5), until the maximum execution times Nₘₐₓ is reached or the model parameter set satisfies the specified precision eps, and taking the model parameter set as an optimized model parameter set; and
7) selecting optimal model parameters from the optimized model parameter set, outputting the optimal model parameters, and substituting the optimal model parameters into an etching yield model parameterization representation formula so as to obtain an etching yield model.

2. The method of claim 1, wherein step 4) specifically comprising:
4.1) with each group of parameters in the model parameter set and the initial parameters of incident ions at specific positions on the surface of the groove as input, calculating the etching rates Vₛ of the incident ions at the specific positions by using the relationship between the etching yield and the etching rates;
4.2) for p groups of grooves with different widths respectively, for the k^{th} group of grooves, calculating the error of the simulated etching rate Vₛ relative to the actual etching rate Vᵣ according to formula (1) as follows:
$${E}_{k} = {\sum }_{i = 1}^{n} {\sum }_{j = 1}^{m} w ( i , j ) {( {V}_{rij} - {V}_{sij} )}^{2} \qquad ( 1 )$$
wherein n indicates the number of different profiles in the evolution process of the k^{th} group of grooves, m indicates the number of the preselected positions on each profile in the evolution process of the k^{th} group of grooves, Vᵣᵢⱼ indicates the actual etching rate of the j^{th} position on the i^{th} profile of the k^{th} group of grooves, Vₛᵢⱼ indicates the simulated etching rate of the j^{th} position on the i^{th} profile of the k^{th} group of grooves, w(i,j) indicates the influence degree of the mean square error of the simulated etching rate of the j^{th} position on the i^{th} profile of the k^{th} group of grooves with respect to the actual etching rate on the global error;
4.3) obtaining the fitness value F=(1/E₁, 1/E₂, . . . , 1/Eₚ) of this group of model parameters according to step 4.2); and
4.4) repeating 4.1)-4.3), and calculating the fitness value of each group of parameters in the model parameter set.

3. A method for modeling an etching yield model in the evolution simulation of a plasma etched surface, the method comprising:
(1) obtaining a set of actual etching rate samples;
(2) selecting a form of the etching yield model, and determining parameters to be determined in the etching yield model; and
(3) optimizing the parameters to be determined in the etching yield model by using a predefined optimization algorithm;
wherein the optimization objective of the optimization algorithm involves minimizing the difference between an actual etching rate and a corresponding simulated etching rate, and the corresponding simulated etching rate is obtained by using the predefined relationship between the etching yield model and the etching rate.

4. The method of claim 3, wherein the obtained actual etching rate samples are p groups of actual etching rates Vᵣ at different etching time points and at different profile positions of etching profiles with different widths, and the etching profiles of each width corresponds to a group of actual etching rates Vᵣ at different etching time points and at different profile positions, wherein p is an integer more than or equal to 1, and the number of each group of actual etching rates Vᵣ at different etching time points and different profile positions is more than or equal to 1.

5. The method of claim 3, wherein the parameters to be determined in the etching yield model is optimized by using a multiobjective evolutionary algorithm based on decomposition, comprising:
1) generating an initial population, and initializing parameters to be optimized and an elite population;
2) performing crossover operation and/or mutation operation on individuals in the population to generate new individuals;
3) for each individual, calculating corresponding simulated etching rates in parallel by using the relationship between the etching yield model and the etching rates, and calculating the fitness value of the individual on the basis of the difference between the actual etching rate and the simulated etching rate;
4) collecting the calculated individuals, performing selection operation on the individuals, and updating the elite population by using an elite retention policy; and
5) determining whether an termination condition is reached, if so, terminating the processing; otherwise, returning to step 2).

6. The method of claim 3, wherein the obtaining the set of actual etching rate samples comprising: selecting a plurality of silicon chips made of a same material and having a same size, performing a same pretreatment on the silicon chips before etching, then etching for different time on the silicon chips with different numbers in a same etching environment, regarding etching profile results of these silicon chips as etching results of a same silicon chip at different moments, and analyzing the etching results of the same silicon chip at different moments to obtain the actual etching rate of each point of each etching profile.

7. The method of claim 6, the obtaining the set of the actual etching rate samples further comprising:
for a given processing profile without actual etching data, simulating an intermediate process by using an etching profile evolution algorithm to obtain the actual etching rate of each point of the given processing profile.

8. The method of claim 3, wherein for the set of actual etching rate samples, a sampling density at the bottom of a groove is greater than that on the lateral surface of the groove.

9. The method of claim 3, wherein the selected form of the etching yield model is as formula (2):
E_{Y}(E₊,θ)=C(\sqrt{E₊}\sqrt{Eₜₕ})ƒ−(θ) (2)
wherein C and Eₜₕ indicate parameters related to an etching process; θ indicates the angle of incident ions; ƒ(θ) indicates a function related to the incident angle; E₊ indicates the energy of the incident ions;
in formula (2), the function ƒ(θ) is as shown in formula (3):
$$f ( θ ) = \{ \begin{matrix}1 & θ \leq {θ}_{cr} \\ \frac{cos θ}{cos {θ}_{cr}} & θ > {θ}_{cr}\end{matrix} \qquad ( 3 )$$
wherein C, Eₜₕ and θ_{cr} are parameters to be optimized for establishing the etching yield model.

10. The method of claim 3, for a specific position, the obtaining the simulated etching rate of the specific position by using the predefined relationship between the etching yield model and the etching rate comprises:
obtaining the etching rate Vₛ_{ᵢ} of the i^{th} kind of ions by using the following predefined relationship between the etching yield E_{Y}_{ᵢ} of the specific position and the etching rate Vₛ_{ᵢ} of the i^{th} kind of incident ions, wherein the predefined relationship is as formula (4):
E_{Y}_{ᵢ}=Vₛ_{ᵢ}Nₜ×/J₊ (4)
wherein E_{Y}_{ᵢ} represents the etching yield of the i^{th} kind of incident ions at the specific position; Vₛ_{ᵢ} represents the etching rate of the i^{th} kind of incident ions at the specific position; Nₜ represents the material density of the i^{th} kind of incident ions; and J₊ represents the flowrate of the i^{th} kind of incident ions;
then the simulated etching rate at the specific position is as shown in formula (5):
$${V}_{s} = {\sum }_{i = 1}^{{N}_{ion}} {V}_{{s}_{i}} \qquad ( 5 )$$
wherein Nᵢₒₙ is the number of kinds of the incident ions.

11. The method of claim 3, wherein the optimization objective of the optimization algorithm involves minimization of the accumulated error sum of the etching profiles with different widths and minimization of the maximum error of etching profiles of a single width.

12. (canceled)

13. (canceled)
